(19) United States
(12) Patent Application Publication
(10) Pub. No.: US 2021/0265996 A1
(43) Pub. Date: Aug. 26, 2021

(54) ROTARY SWITCH APPARATUS FOR A VEHICLE AND METHOD FOR DETERMINING A SWITCH POSITION OF A ROTARY SWITCH

(71) Applicant: ZF Friedrichshafen AG, Friedrichshafen (DE)

(72) Inventors: Hans-Werner NANZ, Mühlacker (DE); Jan SZEKERES-KRISELIUS, Lemfõrde (DE); Jürgen GRIES, Lage (DE)

(73) Assignee: ZF Friedrichshafen AG, Friedrichshafen (DE)

(21) Appl. No.: 17/253,947

(22) PCT Filed: Jun. 28, 2019
(86) PCT No.: PCT/EP2019/067443

§ 371 Date: Dec. 18, 2020

(30) Foreign Application Priority Data
Jul. 2, 2018 (DE) 10 2018 210 830.7

(51) Int. Cl. H03K 17/97; H03K 17/95; H01L 43/04; G01D 5/14

(52) U.S. Cl. CPC H03K 17/97; H03K 17/9517; H03K 2217/94068; G01D 5/145; H03K 2217/94026; H01L 43/04

(57) ABSTRACT

A rotary switch apparatus contains a rotary switch that has a moving operating element that contains a magnetic device for generating a magnetic field. The rotary switch apparatus also contains a Hall sensor device that is configured to generate a sensor signal representing a characteristic of the magnetic field, to determine a position signal using the sensor signal, which indicates a rotation position of the operating element about an actuation axis and a longitudinal position of the operating element along the actuation axis.

The present invention relates to a rotary switch apparatus for a vehicle and a method for determining a switch position of a rotary switch.

Rotary switches are used in vehicles, for example, as operating elements for passengers in the vehicle. The rotary switch can also comprise a so-called “push-down” function, such that the rotary switch can not only be rotated, but also pushed in.

Based on this, the present invention results in an improved rotary switch apparatus for a vehicle and an improved method for determining the position of the rotary switch according to the main claims. Advantageous embodiments can be derived from the dependent claims and the following description.

Advantageously, a switching position of a rotary switch that can be set by both a rotational movement as well as a linear movement is detected using one or more Hall sensors. According to one embodiment, a measurement principle based on one or more Hall sensors can also be used exclusively. A rotational function and push function can therefore be obtained via a single 3-D sensor, or additional sensors.

A rotatory switch apparatus for a vehicle comprises the following features:

a rotary switch with a moving operating element that can rotate about an actuation axis and a move longitudinally along the actuation axis of the operating element, wherein the operating element contains a magnetic mechanism that generates a magnetic field.

a Hall sensor that is configured to output a sensor signal representing a characteristic of the magnetic field; and

a determination device configured to determine a position signal from the sensor signal that indicates a rotational position of the operating element about the actuation axis, and a longitudinal position of the operating element along the actuation axis.

The rotary switch apparatus can be used in a vehicle, e.g. a road vehicle, boat, aircraft, or in conjunction with another device, e.g. a machine. The operating element can be operated by a person, either by rotating it about its actuation axis or by pushing down on it along the actuation axis. The rotary switch apparatus can comprise a mount in which the rotary switch is retained, thus enabling the rotation and longitudinal movement of the operating element. The magnetic mechanism can contain at least one magnet. The magnetic mechanism can be integrated in the operating element or it can be attached thereto. The Hall sensor device can comprise at least one Hall sensor. The Hall sensor device can be placed such that the operating element can rotate and move longitudinally in relation to the Hall sensor device. By way of example, the Hall sensor device can be configured to detect a magnetic flux density of the magnetic field as the characteristic forming the sensor signal. The determination device can comprise an electric circuit. The determination device can be configured to determine the position signal using, e.g., an appropriate determination protocol, a reference table, or a threshold comparison. The position signal can advantageously indicate a position of the operating element resulting not only from a rotation, but also from a longitudinal movement thereof. In this manner, a switch position of the rotatory switch apparatus configured as a rotary and push switch can be indicated.

Advantageously, there is no need for sliding contacts, sliding rings, or levers, which could actuate additional contacts, to identify the vertical position of the operating element. Instead, the vertical position can also be identified using the Hall sensor device, resulting in lower mechanical and electrical complexity.

According to one embodiment, the determination device can be configured to determine the position signal using a temperature signal. The temperature signal can indicate a current ambient temperature at the operating element. Such a temperature signal can be used to compensate for measurement imprecisions caused by different temperatures.

By way of example, the determination device can be configured to determine a sensor signal in which the temperature has been compensated for using the sensor signal and the temperature signal. The determination device can also be configured to determine the position signal using the temperature-adjusted sensor signal. This makes it extremely simple to compensate for temperature differences. The temperature-adjusted sensor signal can be determined, e.g., using a reference table or an appropriate adjustment protocol.

The determination device can be configured to determine the position signal using a predefined reference value assigned to a predefined rotational position and/or a predefined longitudinal position. By way of example, a value of the position signal can be compared with the reference value to determine whether the current position of the operating element corresponds to a position assigned to the reference value. There can also be numerous predetermined reference values that can be assigned to numerous predetermined positions of the operating element, also referred to as settings, or switching settings. This enables a very precise determination of the position of the operating element. According to one embodiment, at least one predetermined rotation reference value assigned to a predetermined rotational position and at least one predetermined longitudinal reference value assigned to a predetermined longitudinal position can also be used to determine the position signal.

The determination device can also be configured to determine the predetermined reference value using the sensor signal in response to a calibration signal. A sensor value transmitted with the sensor signals can be stored for this, e.g., as the predetermined reference value. This makes it very simple to calibrate the rotary switch apparatus.

According to one embodiment, the determination device can be configured to determine a temperature-adjusted reference value using the predetermined reference value and the temperature signal. The determination device can also be configured to determine the position signal using the sensor signal and the temperature-adjusted reference value. As a result, a difference in temperatures between the current ambient temperature and the ambient temperature at the time the reference value was determined can be taken in to account.

By way of example, the determination device can be configured to determine the position signal and a signal indicating a current rotational position of the operating element as one of two possible predetermined rotational positions, and a current longitudinal position of the operating element as one of two possible longitudinal positions of the operating element. The predetermined positions can be assigned to predetermined switch positions.

The magnetic mechanism can be a ring magnet. Both the rotational movement as well as the longitudinal movement can be detected via a ring magnet forming the signal generator.

The Hall sensor device can comprise at least one Hall sensor. Advantageously, the Hall sensor or Hall sensors in the Hall sensor device can be the only sensors used for determining the switch position of the rotary switch apparatus. According to one embodiment, the Hall sensor used for detecting the rotational movement can also be used to detect the longitudinal movement. If numerous Hall sensors are used, the Hall sensors used for detecting the rotational movement can also be used to detect longitudinal movements. This means that there is no need for a separate sensor system to detect longitudinal positions that can be assumed by the operating element. The at least one Hall sensor can therefore be configured to detect a change in the characteristic of the magnetic field caused by either the rotational movement or the longitudinal movement.

According to one embodiment, the Hall sensor device only contains one single 3D Hall sensor. Such a sensor can be used to detect a three dimensional vector of the magnetic flux density of the magnetic field. This single sensor can be used to detect both the longitudinal position as well as the rotational position assumed by the operating element.

A method for determining a switch position of a rotary switch that has a moving operating element that can rotate about an actuation axis and move longitudinally along the actuation axis of the operating element, wherein the operating element contains a magnetic device that generates a magnetic field, can comprise the following steps:

inputting a sensor signal via an interface to a Hall sensor device configured to generate a sensor signal representing a characteristic of the magnetic field; and

determining a position signal using the sensor signal, wherein the position signal indicates a rotational position of the operating element about the actuation axis, and longitudinal position of the operating element along the actuation axis.

The steps of the method can be carried out using a determination device. The determination device can be an electric device that processes electric signals, e.g. sensor signals, and outputs control signals based thereon. The device can contain one or more appropriate hardware and/or software interfaces. A hardware interface can be part of an integrated circuit, for example, in which functions of the device are implemented. The interfaces can also be autonomous, integrated circuits or at least partially comprised of discrete components. Software interfaces can be software modules on a microcontroller, in addition to other software modules.

The invention shall be explained in greater detail by way of example, based on the attached drawings. Therein:

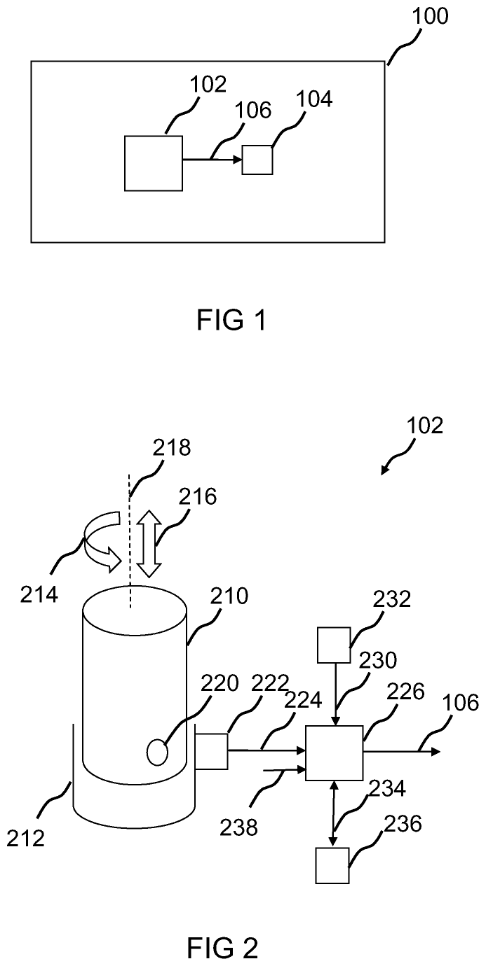

FIG. 1 shows a vehicle that has a rotary switch apparatus according to an exemplary embodiment;

FIG. 2 shows a rotary switch apparatus for a vehicle according to an exemplary embodiment;

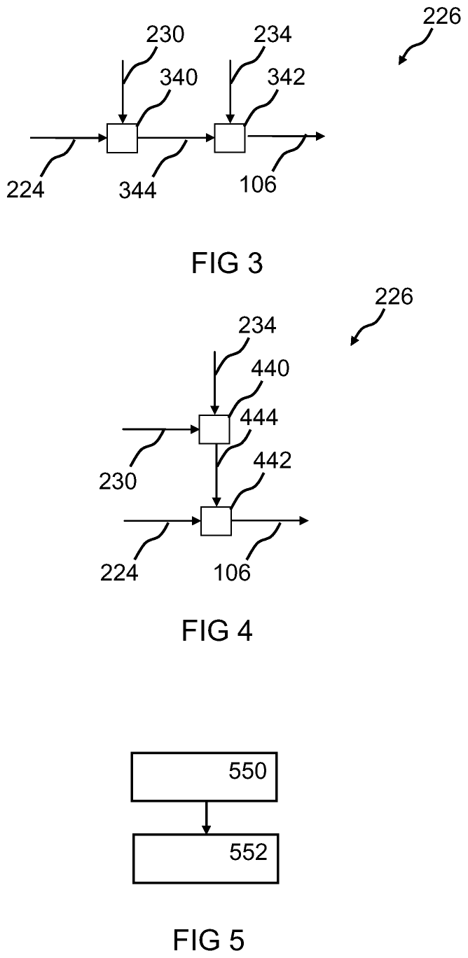

FIG. 3 shows a determination device for a rotary switch apparatus according to an exemplary embodiment;

FIG. 4 shows a determination device for a rotary switch apparatus according to an exemplary embodiment; and

FIG. 5 shows a flow chart for a method for determining a switch position of a rotary switch according to an exemplary embodiment.

In the following description of exemplary embodiments of the invention, the same or similar reference symbols are used for elements with similar functions shown in the various figures, such that there shall be no repetition of the descriptions of these elements.

FIG. 1 shows a vehicle 100 that has a rotary switch apparatus 102 according to an exemplary embodiment. By way of example, the rotary switch apparatus 102 is used to enable an operator to operate a component 104 in the vehicle 100, e.g. an information system for the vehicle 100. The rotary switch apparatus 102 is configured to output a position signal 106 indicating a switch position of the rotary switch apparatus 102. By way of example, the position signal 106 is used by the component 104, or a control unit is used, to control a function of the component 104.

The use of the rotary switch apparatus 102 in the vehicle is selected by way of example herein. The rotary switch apparatus 102 can be used in general to operate a machine.

FIG. 2 shows a schematic illustration of a rotary switch apparatus 102 according to an exemplary embodiment. By way of example, this can be the rotary switch apparatus 102 shown in FIG. 1 and located in a vehicle.

The rotary switch apparatus 102 contains a rotary switch that has an operating element 210 that can be operated by an operator. By way of example, the operating element 210 is moveably supported in a bearing element 212 such that it can be rotated or pushed by the operator. According to this exemplary embodiment, the rotary switch is designed such that the operating element 210 can rotate 214 about, and move longitudinally 216 along an actuation axis 218. The operating element 210 is cylindrical, merely by way of example.

The operating element 210 comprises a magnetic device 220, e.g. a permanent magnet. The magnetic device 220 is configured to generate a magnetic field. When the operating element 210 is moved, the magnetic device 220 moves with it. According to one exemplary embodiment, the magnetic device 220 is in the form of a ring magnet, which encompasses the operating element 220, for example.

The rotary switch apparatus 102 contains a Hall sensor device 222, which is decoupled from the operating element 210. By way of example, the Hall sensor device 222 is attached to the bearing element 212. The Hall sensor device 222 is configured to detect a characteristic of the magnetic field generated by the magnetic device 220, and output a sensor signal 224 representing this characteristic. The characteristic of the magnetic field changes when the operating element 210 moves, such that the sensor signal 224 is able to indicate a movement and/or a setting, also referred to as a position, of the operating element 210.

The Hall sensor device 222 comprises just one Hall sensor, or two or more Hall sensors, according to different exemplary embodiments. By way of example, the Hall sensor device 222 comprises one or more 3D Hall sensors. The sensor signal 224 can therefore be composed of one or more individual signals. The at least one Hall sensor in the Hall sensor device is configured, according to one exemplary embodiment, to detect a change in the characteristic of the magnetic field caused by the rotation 214 or by the longitudinal movement. By way of example, the characteristic is a magnitude and/or direction of the magnetic flux density of the magnetic field.

The rotary switch apparatus 102 also contains a determination device 226. The determination device 226 is configured to determine a position signal 106 using the sensor signal 224 that indicates the setting of the operating element 210. According to one exemplary embodiment, the position signal 106 is configured to indicate a rotational position of the operating element 210 about the actuation axis 218, and a longitudinal position of the operating element 210 along the actuation axis 218.

According to one exemplary embodiment, the determination device 226 is configured to determine the position signal 106 using a temperature signal 230, which indicates, e.g., the current ambient temperature at the operating element 210. The temperature signal 230 is generated, e.g., by a temperature sensor 232, which can be part of the rotary switch apparatus 102.

According to one exemplary embodiment, the determination device 226 is configured to determine the position signal using a reference value 234 assigned to a predetermined position, e.g. a predetermined rotational position and/or a predetermined longitudinal position of the operating element 210. By way of example, the predetermined reference value 234 is stored in a memory 236, which can be part of the rotary switch apparatus 102. According to one exemplary embodiment, the determination device 226 is configured to determine the predetermined reference value 234 using the sensor signal 224 in response to a calibration signal 238. By way of example, a calibration involves bringing the operating element into a predetermined position, and subsequently storing the sensor signal 224, or a signal based on the sensor signal 224, as the predetermined reference value 234. The calibration signal then indicates that the operating element 210 has been moved into the predetermined position.

According to one exemplary embodiment, numerous reference values 234 are used, which are assigned to different switch positions. By way of example, a first value indicates that the operating element has neither been pushed nor rotated, a second value indicates that the operating element has not been pushed but has been rotated, a third value indicates that the operating element has been pushed but not rotated, and a fourth value indicates that the operating element has been pushed and rotated. The operating element can be locked into the current longitudinal position, for example, by rotating the operating element.

According to one exemplary embodiment, the rotary switch apparatus 102 is configured such that the so-called “push-down” function can allow the rotary switch to assume numerous different vertical positions. The various vertical positions can be set through the longitudinal movement 216 of the operating element 210. The rotary switch apparatus 102 advantageously allows for the push-down function without additional sensors or other mechanical contacts or levers that would be necessary, in addition to one or more sensors that detect rotational movement 214. The rotational movement 214 is detected, e.g. by one or more 2D or 3D Hall sensor(s) in the Hall sensor device 22, which detect the magnetic field from the magnetic device 220, e.g. a ring magnet.

Advantageously, no sliding contacts, sliding rings, levers, or similar elements are used according to one exemplary embodiment, for identifying the vertical position, which would actuate additional contacts. To reduce the mechanical and electrical complexity, the vertical position is also detected via 2D or 3D sensors according to one exemplary embodiment. The third dimension is identified, e.g., via the field strengths of the magnetic field generated by the magnetic device 220.

For a reliable identification of the various positions of the operating element 210, addition measures are carried out in a series according to different exemplary embodiments.

According to one exemplary embodiment, the sensor system, i.e. the Hall sensor device 222 and/or the determination device 226, is taught to determine the exact field strengths of the magnetic device 220 at a predetermined temperature, e.g. room temperature.

According to one exemplary embodiment, the stored switching point, e.g. in the form of the reference value 234 or numerous reference values, is offset in relation to the current temperature.

Even if tolerances are eliminated, robust switching points are difficult to obtain for the rotary switch apparatus 102. According to one exemplary embodiment, an additional compensation for the temperature results in stable detectible positions. These measures allow for a reliable distinction between up and down, i.e. whether the operating element 210 is in a retracted or extended position. By way of example, the bearing element 212 contains a blocking mechanism, allowing the operating element 210 to be locked into the pushed-in position by rotating 214 it. The operating element 210 can be released by rotating 214 it in the other direction, for example.

According to one exemplary embodiment, the position signal 106 is configured to indicate the specified position, or, according to another exemplary embodiment, to also indicate other positions of the operating element 210. A reference value can be recorded for each of the positions when the rotary switch apparatus is initially operated, and stored as a predetermined reference value.

FIG. 3 shows a determination device 226 in a rotary switch apparatus according to an exemplary embodiment. This is the determination device 226 shown in FIG. 2. The determination device is configured to receive or read a sensor signal 224, and generate a position signal 106 using the sensor signal 224, which indicates one or more switch positions in the rotary switch apparatus, as described in reference to FIG. 2.

According to this exemplary embodiment, the determination device 226 comprises a first determination device 340 and a second determination device 342. The first determination device 340 is configured to determine a temperature-adjusted sensor signal 344 using the sensor signal 224 and a temperature signal 230, as described by way of example in reference to FIG. 2. The second determination device 342 is configured to determine the position signal 106 using the temperature-adjusted sensor signal 344. In this manner, effects due to varying temperatures that make it difficult to identify the switch position are compensated for.

According to one exemplary embodiment, the second determination device 342 is configured to determine the position signal 106 using at least one predetermined reference value 234, as described by way of example in reference to FIG. 2. The temperature-adjusted sensor signal 342 can be compared with the at least one predetermined reference value 234, and the position signal 106 can be determined using the result of the comparison, or it can reproduce the result.

FIG. 4 shows a determination device 226 for a rotary switch apparatus according to an exemplary embodiment. This is the determination device 226 described in reference to FIG. 2. The determination device 226 is configured to receive or read a sensor signal 224, and to generate a position signal 106 using the sensor signal 224, which indicates one or more switch positions in the rotary switch apparatus, as described in reference to FIG. 2.

According to this exemplary embodiment, the determination device 226 comprises a third determination device 440, and a fourth determination device 442. The third determination device 440 is configured to determine a temperature-adjusted reference value 444 using at least one predetermined reference value 234, as described in reference to FIG. 2, and a temperature signal 230, as described in reference to FIG. 2. In this manner, the predetermined reference value 234, which defines, e.g., an assignment of a predetermined switch position to a signal state of the sensor signal 224 at a predetermined temperature, e.g. room temperature, can be adjusted to another temperature indicated by the temperature signal 230. A reference table or adjustment guideline can be used for this. The fourth determination device 442 is configured to determine the position signal 106 using the sensor signal 224 and the temperature-adjusted reference value 444. By way of example, the sensor signal 342 can be compared with the at least one temperature-adjusted reference value 444, and the position signal 106 can be determined using the result of the comparison, or it can reproduce the result.

FIG. 5 shows a flow chart for a method for determining a switch position in a rotary switch according to an exemplary embodiment. The method can be carried out using the elements in a rotary switch apparatus, as described in reference to the preceding figures.

A sensor signal is input in step 550 via an interface to a Hall sensor device, which is configured to generate a sensor signal representing a characteristic of a magnetic field. The magnetic field can be generated by a magnetic device, as described in reference to FIG. 2, for example.

A position signal is determined in step 552 using the sensor signal. The position signal indicates a rotary switch position, e.g. a rotational position of the operating element in the rotary switch about the actuation axis, and a longitudinal position of the operating element along the actuation axis.

Steps 550 and 552 can be repeated continuously or in response to an actuation of the operating element, for example. In this manner, the position signal can always indicate a current switch position in the rotary switch apparatus.

If an exemplary embodiment comprises an “and/or” conjunction between a first feature and a second feature, this can be read to mean that the exemplary embodiment according to one embodiment contains both the first feature and the second feature, and contains either just the first feature or just the second feature according to another embodiment.

### REFERENCE SYMBOLS

100 vehicle
102 rotary switch apparatus
104 components
106 position signal
210 operating element
212 bearing element
214 rotational movement
216 longitudinal movement
218 actuation axis
220 magnetic device
222 Hall sensor device
224 sensor signal
226 determination device
230 temperature signal
232 temperature sensor
234 predetermined reference value
236 memory
238 calibration signal
340 first determination device
342 second determination device
344 temperature-adjusted sensor signal
440 third determination device
442 fourth determination device
444 temperature-adjusted reference value
550 input step
552 determination step

1. A rotary switch apparatus for a vehicle, the rotary switch apparatus comprising:
a rotary switch comprising a moving operating element configured to rotate about an actuation axis and move longitudinally along a longitudinal axis of the operating element, wherein the operating element comprises a magnetic device that generates a magnetic field;
a Hall sensor device configured to generate a sensor signal representing a characteristic of the magnetic field; and
a determination device configured to determine a position signal using the sensor signal, which indicates a rotational position of the operating element about the actuation axis and a longitudinal position of the operating element along the actuation axis.

2. The rotary switch apparatus according to claim 1, wherein the determination device is configured to determine the position signal using, at least in part, a temperature signal that indicates a current ambient temperature at the operating element.

3. The rotary switch apparatus according to claim 2, wherein the determination device is configured to determine a temperature-adjusted sensor signal using the sensor signal and the temperature signal, and is configured to determine the position signal using the temperature-adjusted sensor signal.

4. The rotary switch apparatus according to claim 1, wherein the determination device is configured to determine the position signal using a predetermined reference value assigned to at least one of a predetermined rotational position or a predetermined longitudinal position.

5. The rotary switch apparatus according to claim 4, wherein the determination device is configured to determine the predetermined reference value in response to a calibration signal using the sensor signal.

6. The rotary switch apparatus according to claim 4, wherein the determination device is configured to determine a temperature-adjusted reference value using the predetermined reference value and a temperature signal that indicates a current ambient temperature at the operating element, and is configured to determine the position signal using the sensor signal and the temperature-adjusted reference value.

7. The rotary switch apparatus according to claim 1, wherein the magnetic device is a ring magnet.

8. The rotary switch apparatus according to claim 1, wherein the Hall sensor device comprises at least one 3D Hall sensor.

9. The rotary switch apparatus according to claim 8, wherein the at least one 3D Hall sensor is configured to detect a change in the characteristic of the magnetic field caused by a rotational movement or by a longitudinal movement.

10. A method for determining a switch position of a rotary switch that has a moving operating element configured to rotate about a rotational axis or move longitudinally along the rotational axis of the operating element, wherein the operating element contains a magnetic device for generating a magnetic field, and wherein the method comprises:
generating, by a Hall sensor device, a sensor signal representing a characteristic of the magnetic field;
inputting, by a determination device, the sensor signal via an interface; and
determining, by the determination device, a position signal using the sensor signal, wherein the position signal indicates a rotational position of the operating element about an actuation axis and a longitudinal position of the operating element along the actuation axis.

11. The method according to claim 10, further comprising:
determining, by the determination device, the position signal using, at least in part, a temperature signal that indicates a current ambient temperature at the operating element.

12. The method according to claim 11, further comprising:
determining, by the determination device, a temperature-adjusted sensor signal using the sensor signal and the temperature signal; and
determining, by the determination device, the position signal using the temperature-adjusted sensor signal.

13. The method according to claim 10, further comprising:
determining, by the determination device, the position signal using a predetermined reference value assigned to at least one of a predetermined rotational position or a predetermined longitudinal position.

14. The method according to claim 13, further comprising:
determining, by the determination device, the predetermined reference value in response to a calibration signal using the sensor signal.

15. The method according to claim 13, further comprising:
determining, by the determination device, a temperature-adjusted reference value using the predetermined reference value and a temperature signal that indicates a current ambient temperature at the operating element; and
determining, by the determination device, the position signal using the sensor signal and the temperature-adjusted reference value.

16. The rotary switch apparatus according to claim 8, wherein the at least one 3D Hall sensor comprises a single 3D Hall sensor.

17. The rotary switch apparatus according to claim 6, wherein the determination device is configured to determine the predetermined reference value in response to a calibration signal using the sensor signal.

18. The rotary switch apparatus according to claim 2, wherein the determination device is configured to determine the position signal using a predetermined reference value assigned to at least one of a predetermined rotational position or a predetermined longitudinal position.
